(19) United States
(12) Patent Application Publication
(10) Pub. No.: US 2025/0336665 A1
(43) Pub. Date: Oct. 30, 2025

(54) ELECTROCHEMICAL REDUCTION OF SURFACE METAL OXIDES

(71) Applicant: Applied Materials, Inc., Santa Clara, CA (US)

(72) Inventors: Haotian YANG, Santa Clara, CA (US); Yoon Ah SHIN, Santa Clara, CA (US); Mohammad Mahdi TAVAKOLI, Santa Clara, CA (US); Bencherki MEBARKI, Santa Clara, CA (US); Joung Joo LEE, San Jose, CA (US); Xianmin TANG, San Jose, CA (US); Thai Cheng CHUA, Cupertino, CA (US); Christian W. VALENCIA, Santa Clara, CA (US)

(21) Appl. No.: 19/263,848

(22) Filed: Jul. 9, 2025

Related U.S. Application Data
(63) Continuation-in-part of application No. 18/077,225, filed on Dec. 7, 2022.

(51) Int. Cl. H01L 21/02; C23G 5/00

(52) U.S. Cl. CPC H01L 21/0206; C23G 5/00

(57) ABSTRACT

Embodiments of the disclosure generally relate to methods for converting surface metal oxides to pure metal. In particular, embodiments of the disclosure pertain to methods for reducing metal oxides by microwave process. In some embodiments, a method includes positioning a semiconductor structure within a processing chamber. The semiconductor structure includes an SiO₂ layer deposited on a substrate surface, a hardmask layer deposited over the SiO₂ layer, a feature formed from a low-k dielectric material deposited over a portion of the hardmask layer, and a metal layer deposited in the feature. The metal layer includes a molybdenum (Mo) layer and a molybdenum oxide layer (MoOx). The method further includes flowing a process gas into the processing chamber. The process gas includes carbon monoxide. The method further includes applying a microwave energy to the process gas to perform a redox operation on a portion of the semiconductor structure.

### CROSS-REFERENCE TO RELATED APPLICATION

This application is a continuation-in-part of, and claims priority to, U.S. patent application Ser. No. 18/077,225, filed Dec. 7, 2022, which is incorporated herein by reference.

### BACKGROUND

### Field

Embodiments of the disclosure generally relate to methods for converting surface metal oxides to pure metal. In particular, embodiments of the disclosure pertain to methods for reducing metal oxides by microwave process.

### Description of the Related Art

Exposing pure metal materials to air can result in a thin layer of metal oxide being formed on the surface of the metal. This surface layer of metal oxide can interfere with the selectivity of subsequent processing steps and increase resistance of interconnects. Accordingly, there is a need for methods of preventing and/or cleaning metal oxides from the surface of metal materials.

While integrated processing apparatus and transportation of wafers under vacuum has decreased the need for removal of these metal oxide layers, the current preclean methods typically require a hydrogen plasma, high processing temperatures (greater than 300° C.), and/or high energy argon (Ar) sputtering. However, these processes can often damage adjacent dielectric materials (e.g., feature sidewalls) and adversely affect the selectivity of many metal deposition processes (e.g., selective tungsten deposition).

Also, current preclean methods need to be developed and/or tuned for different metal oxide materials (e.g., WOx, MoOx, CoOx, RuOx, CuOx, etc). Each different material may requires a different plasma source, different reactant gas mixtures or chemical soaks, and/or different processing conditions (e.g., temperature, pressure).

Accordingly, there is a need for universal methods of converting surface metal oxides to pure metal. Further, there is particular need for processes performed at relatively low temperatures without damaging surrounding materials.

### SUMMARY

Embodiments of the disclosure generally relate to methods for converting surface metal oxides to pure metal. In particular, embodiments of the disclosure pertain to methods for reducing metal oxides by microwave process.

In some embodiments, a method includes positioning a semiconductor structure within a processing chamber. The semiconductor structure includes an SiO₂ layer deposited on a substrate surface, a hardmask layer deposited over the SiO₂ layer, a feature formed from a low-k dielectric material deposited over a portion of the hardmask layer, and a metal layer deposited in the feature. The metal layer includes a molybdenum (Mo) layer and a molybdenum oxide layer (MoOx). The method further includes flowing a process gas into the processing chamber. The process gas includes carbon monoxide. The method further includes applying a microwave energy to the process gas to perform a redox operation on a portion of the semiconductor structure.

In some embodiments, a method includes positioning a semiconductor structure within a processing chamber. The semiconductor structure includes an SiO₂ layer deposited on a substrate surface, a hardmask layer deposited over the SiO₂ layer, a feature formed from a low-k dielectric material deposited over a portion of the hardmask layer, and a metal layer deposited in the feature. The metal layer includes a molybdenum (Mo) layer and a molybdenum oxide layer (MoOx). The method further includes flowing a process gas into the processing chamber. The process gas includes carbon monoxide. The method further comprises applying a microwave energy to the process gas to perform a redox operation on a portion of the semiconductor structure. The microwave energy is applied at a first power level that is about 1% to about 10% below a second power level. The second power level is a lowest power level that generates a plasma.

In some embodiments, a method includes positioning a semiconductor structure within a processing chamber. The semiconductor structure includes an SiO₂ layer deposited on a substrate surface, a hardmask layer deposited over the SiO₂ layer, a feature formed from a low-k dielectric material deposited over a portion of the hardmask layer, and a metal layer deposited in the feature. The metal layer includes a first layer having molybdenum (Mo) and a second layer having molybdenum oxide (MoOx). The method further includes flowing a process gas into the processing chamber. The process gas includes carbon monoxide. The method further includes applying a microwave energy to the process gas to perform a redox operation on a portion of the semiconductor structure. Greater than about 95% of the MoOx is converted to Mo.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 illustrates a schematic top view of a multi-chamber processing system, according to embodiments described herein.

FIG. 2 is a schematic of a processing chamber that includes a microwave source, in accordance with an embodiment.

FIG. 3 is a schematic of a processing chamber that includes a microwave source, in accordance with an embodiment.

FIG. 4 is a schematic of a solid state microwave emission module, in accordance with an embodiment.

FIG. 5 is a perspective view illustration of a source array for a microwave source, in accordance with an embodiment.

FIG. 6 is a cross-sectional illustration of a processing chamber for processing a substrate, in accordance with an embodiment.

FIG. 7A illustrates an exemplary substrate during processing, in accordance with an embodiment.

FIG. 7B illustrates an exemplary substrate during processing, in accordance with an embodiment.

FIG. 7C illustrates a cross-sectional view of an exemplary substrate, in accordance with an embodiment.

FIG. 8 is a flow diagram depicting a method, in accordance to an embodiment.

FIG. 9A is a cross-sectional view of a semiconductor structure, in accordance to an embodiment.

FIG. 9B is a cross-sectional view of a semiconductor structure, in accordance to an embodiment.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

The term “about” as used herein means approximately or nearly and in the context of a numerical value or range set forth means a variation of ±15% or less, of the numerical value. For example, a value differing by ±14%, ±10%, ±5%, ±2%, ±1%, ±0.5%, or ±0.1% would satisfy the definition of “about.”

As used in this specification and the appended claims, the term “substrate” or “wafer” refers to a surface, or portion of a surface, upon which a process acts. It will also be understood by those skilled in the art that reference to a substrate can refer to only a portion of the substrate, unless the context clearly indicates otherwise. Additionally, reference to depositing on a substrate can mean both a bare substrate and a substrate with one or more films or features deposited or formed thereon.

A “substrate surface” as used herein, refers to any substrate or material surface formed on a substrate upon which film processing is performed during a fabrication process. For example, a substrate surface on which processing can be performed include materials such as silicon, silicon oxide, strained silicon, silicon on insulator (SOI), carbon doped silicon oxides, amorphous silicon, doped silicon, germanium, gallium arsenide, and any other materials such as metals, metal nitrides, metal alloys, and other conductive materials, depending on the application. Substrates include, without limitation, semiconductor wafers. Substrates may be exposed to a pretreatment process to polish, etch, reduce, oxidize, hydroxylate, anneal and/or bake the substrate surface. In addition to film processing directly on the surface of the substrate itself, in the present disclosure, any of the film processing steps disclosed may also be performed on an under-layer formed on the substrate as disclosed in more detail below, and the term “substrate surface” is intended to include such under-layer as the context indicates. Thus, for example, where a film/layer or partial film/layer has been deposited onto a substrate surface, the exposed surface of the newly deposited film/layer becomes the substrate surface.

The substrate surface may have one or more features formed therein, one or more layers formed thereon, and combinations thereof. The shape of the feature can be any suitable shape including, but not limited to, trenches, holes and vias (circular or polygonal). As used in this regard, the term “feature” refers to any intentional surface irregularity. Suitable examples of features include but are not limited to trenches, which have a top, two sidewalls and a bottom extending into the substrate, and vias which have one or more sidewall extending into the substrate to a bottom.

The term “on” indicates that there is direct contact between elements. The term “directly on” indicates that there is direct contact between elements with no intervening elements.

As used in this specification and the appended claims, the terms “precursor”, “reactant”, “reactive gas” and the like are used interchangeably to refer to any gaseous species that can react with the substrate surface.

Embodiments of the disclosure advantageously provide methods for reducing surface metal oxides at relatively low temperatures without affecting neighboring materials. Specific embodiments advantageously provide methods of reducing metal oxides which utilize a microwave process. In some embodiments, the metal oxide layer is not exposed to a plasma.

The embodiments of the disclosure are described by way of the figures, which illustrate processes, substrates and apparatus in accordance with one or more embodiments of the disclosure. The processes, schemes, and resulting substrates shown are merely illustrative of the disclosed processes, and the skilled artisan will recognize that the disclosed processes are not limited to the illustrated applications.

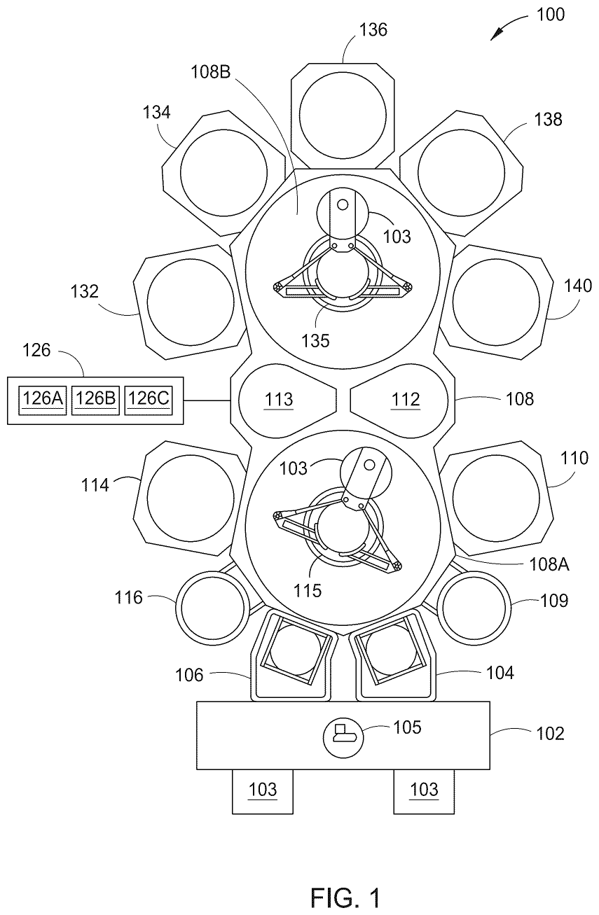

FIG. 1 illustrates a schematic representation of a processing system 100 for use with one or more embodiments of the disclosure. As detailed below, substrates in the processing system 100 may be processed in and transferred between the various chambers without exposing the substrates to an ambient environment exterior to the processing system 100 (for example, an atmospheric ambient environment such as may be present in a fab). For example, the substrates may be processed in and transferred between the various chambers maintained at a low pressure (for example, less than or equal to about 300 Torr) or sub-atmospheric pressure, such as a vacuum environment, without breaking the reduced relative pressure or vacuum environment among various processes performed on the substrates in the processing system 100. Accordingly, the processing system 100 may provide for an integrated solution for some processing of substrates.

Examples of a processing system that may be suitably modified in accordance with the teachings provided include the Endura®, Producer® or Centura® integrated processing systems or other suitable processing systems commercially available from Applied Materials, Inc., located in Santa Clara, California (CA), United States of America. One may envision that other processing systems, including those from other manufacturers, may be adapted to benefit from aspects described.

FIG. 1 is a schematic top view of the processing system 100 (also referred to as a “processing platform”), according to embodiments described herein. The processing system 100 generally includes an equipment front-end module (EFEM) 102 for loading substrates into the processing system 100, a first load lock chamber 104 coupled to the EFEM 102, a transfer chamber 108 coupled to the first load lock chamber 104, and a plurality of other chambers coupled to the transfer chamber 108 as described in detail below. The EFEM 102 generally includes one or more robots 105 that are configured to transfer substrates from the front opening unified pods (FOUPs) 103 to at least one of the first load lock chamber 104 or the second load lock chamber 106. Proceeding counterclockwise around the transfer chamber 108 from the buffer portion 108A of the first load lock chamber 104, the processing system 100 includes a first dedicated degas chamber 109, a first pre-clean chamber 110, a first pass-through chamber 112, a second pass-through chamber 113, a second pre-clean chamber 114, a second degas chamber 116 and the second load lock chamber 106. The buffer portion 108A of the transfer chamber 108 includes a first robot 115 that is configured to transfer substrates to each of the load lock chambers 104, 106, the degas chambers 109, 116, the pre-clean chambers 110, 114 and the pass-through chambers 112, 113.

The back-end portion 108B of the transfer chamber 108 includes a second robot 135 that is configured to transfer substrates to each of the pass-through chambers 112, 113 and the processing chambers coupled to the back-end portion 108B of the processing system 100. The processing chambers can include a first processing chamber 132, a second processing chamber 134, a third processing chamber 136, a fourth processing chamber 138 and a fifth process chamber 140. In general, the processing chambers 132, 134, 136, 138, 140 can include at least one of an atomic layer deposition (ALD) chamber, chemical vapor deposition (CVD) chamber, physical vapor deposition (PVD) chamber, etch chamber, degas chamber, an anneal chamber, and other type of semiconductor substrate processing chamber. In some embodiments, one or more of the processing chambers 132, 134, 136, 138, 140 are a PVD chamber. In some examples, the pre-clean chamber 110 may be capable of performing an etch process, the pre-clean chamber 114 may be capable of performing a cleaning process or an annealing process, and the processing chambers 132, 134, 136, 138, 140 may be capable of performing respective CVD or ALD deposition processes. In one example, the processing chambers 132, 134, 136, 138, or 140 may be a Volta™ CVD/ALD chamber, or Encore™ PVD chambers available from Applied Materials of Santa Clara, Calif.

The buffer portion 108A and back-end portion 108B of the transfer chamber 108 and each chamber coupled to the transfer chamber 108 may be maintained at a vacuum state. As used herein, the term “vacuum” may refer to pressures less than 760 Torr, and will typically be maintained at pressures near 10⁻⁵ Torr (that is, ˜10⁻³ Pa). However, some high-vacuum systems may operate below near 10⁻⁷ Torr (that is, ˜10⁻⁵ Pa). In certain embodiments, the vacuum is created using a rough pump and/or a turbomolecular pump coupled to the transfer chamber 108 and to each of the one or more process chambers (for example, process chambers 109-140). However, other types of vacuum pumps are also contemplated.

A system controller 126, such as a programmable computer, is coupled to the processing system 100 for controlling one or more of the components therein. For example, the system controller 126 may control the operation of one or more of the processing chambers, such as processing chambers 132, 134, 136, 138, 140. In operation, the system controller 126 enables data acquisition and feedback from the respective components to coordinate processing in the processing system 100.

The system controller 126 includes a programmable central processing unit (CPU) 126A, which is operable with a memory 126B (for example, non-volatile memory) and support circuits 126C. The support circuits 126C (for example, cache, clock circuits, input/output subsystems, power supplies, etc., and combinations thereof) are conventionally coupled to the CPU 126A and coupled to the various components within the processing system 100.

In some embodiments, the CPU 126A is one of any form of general purpose computer processor used in an industrial setting, such as a programmable logic controller (PLC), for controlling various monitoring system component and sub-processors. The memory 126B, coupled to the CPU 126A, is non-transitory and is typically one or more of readily available memory such as random access memory (RAM), read only memory (ROM), floppy disk drive, hard disk, or any other form of digital storage, local or remote.

Herein, the memory 126B is in the form of a computer-readable storage media containing instructions (for example, non-volatile memory), that when executed by the CPU 126A, facilitates the operation of the processing system 100. The instructions in the memory 126B are in the form of a program product such as a program that implements the methods of the present disclosure (for example, middleware application, equipment software application, etc.). The program code may conform to any one of a number of different programming languages. In one example, the disclosure may be implemented as a program product stored on computer-readable storage media for use with a computer system. The program(s) of the program product define functions of the embodiments (including the methods described herein). Illustrative computer-readable storage media include, but are not limited to: (i) non-writable storage media (for example, read-only memory devices within a computer such as CD-ROM disks readable by a CD-ROM drive, flash memory, ROM chips or any type of solid-state non-volatile semiconductor memory) on which information is permanently stored; and (ii) writable storage media (for example, floppy disks within a diskette drive or hard-disk drive or any type of solid-state random-access semiconductor memory) on which alterable information is stored. Such computer-readable storage media, when carrying computer-readable instructions that direct the functions of the methods described herein, are embodiments of the present disclosure. The various methods disclosed herein may generally be implemented under the control of the CPU 126A by the CPU 126A executing computer instruction code stored in the memory 126B (or in memory of a particular processing chamber) as, for example, a software routine. When the computer instruction code is executed by the CPU 126A, the CPU 126A controls the chambers to perform processes in accordance with the various methods.

As will be described further below, in one or more embodiments of the substrate processing sequence described herein, all of the processes are performed under vacuum within the processing system 100. In one example of the processing system 100, a remote-plasma-source (RPS) cleaning process is performed in pre-clean chamber 110, a precleaning process is performed in pre-clean chamber 114, and one or more of a deposition, an etching, and/or a thermal processing process is performed in at least one of the processing chambers 132, 134, 136, 138, and 140. In one example, the remote plasma (RPS) assisted process performed in pre-clean chamber 110 is performed in a processing chamber, such as Aktiv™ Preclean (APC) chamber available from Applied Materials of Santa Clara, Calif. In another example, the processing chambers 132, 134, 136, 138, or 140 may be a Volta™ CVD/ALD chamber, or Encore™ PVD chambers available from Applied Materials of Santa Clara, Calif.

In another example of the processing system 100, a remote-plasma-source (RPS) cleaning process and a precleaning process are both performed in at least one of the pre-clean chambers 110 and 114, and one or more of a deposition, an etching, and/or a thermal processing process is performed in at least one of the processing chambers 132, 134, 136, 138, and 140. In one example, the processing chambers 132, 134, 136, 138, or 140 may be a Volta™ CVD/ALD chamber, or Encore™ PVD chambers available from Applied Materials of Santa Clara, Calif.

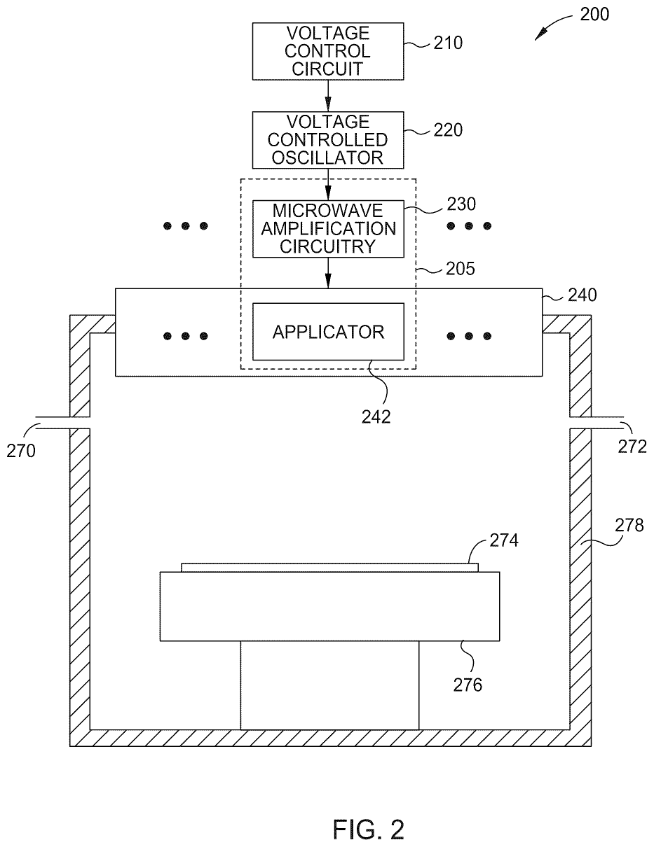

Referring to FIG. 2, a cross-sectional illustration of an exemplary processing tool 200 is shown. The processing tool 200 may be a processing tool suitable for any type of processing operation that utilizes microwaves. While the embodiments described in detail herein are directed to microwave processing methods, it is to be appreciated that additional processing methods (including plasma processing methods) may also be practiced on processing tool 200. Further, it is also to be appreciated that the PEALD methods described herein may also be performed using differing processing tools.

Generally, the processing tool 200 includes a chamber 278. In processing tools 200 that are used for substrate processing, the chamber 278 may be a vacuum chamber. A vacuum chamber may include a pump (not shown) for removing gases from the chamber to provide the desired vacuum. Additional embodiments may include a chamber 278 that includes one or more gas lines 270 for providing processing gasses into the chamber 278 and exhaust lines 272 for removing byproducts from the chamber 278. While not shown, it is to be appreciated that the processing tool may include a showerhead or other gas distribution assembly for evenly distributing the processing gases over a substrate 274.

In some embodiments, the substrate 274 may be supported on a chuck 276. For example, the chuck 276 may be any suitable chuck, such as an electrostatic chuck. The chuck may also include cooling lines and/or a heater to provide temperature control to the substrate 274 during processing.

The processing tool 200 includes one or more microwave sources 204. The microwave source 204 may include solid state microwave amplification circuitry 230 and an applicator 242. In some embodiments, a voltage control circuit 210 provides an input voltage to a voltage controlled oscillator 220 in order to produce microwave radiation at a desired frequency that is transmitted to the solid state microwave amplification circuitry 230 in each microwave source 204. After processing by the microwave amplification circuitry 230, the microwave radiation is transmitted to the applicator 242. In some embodiments, an array 240 of applicators 242 are coupled to the chamber 278 and each function as an antenna for coupling the microwave radiation to the substrate 274 in the chamber 278.

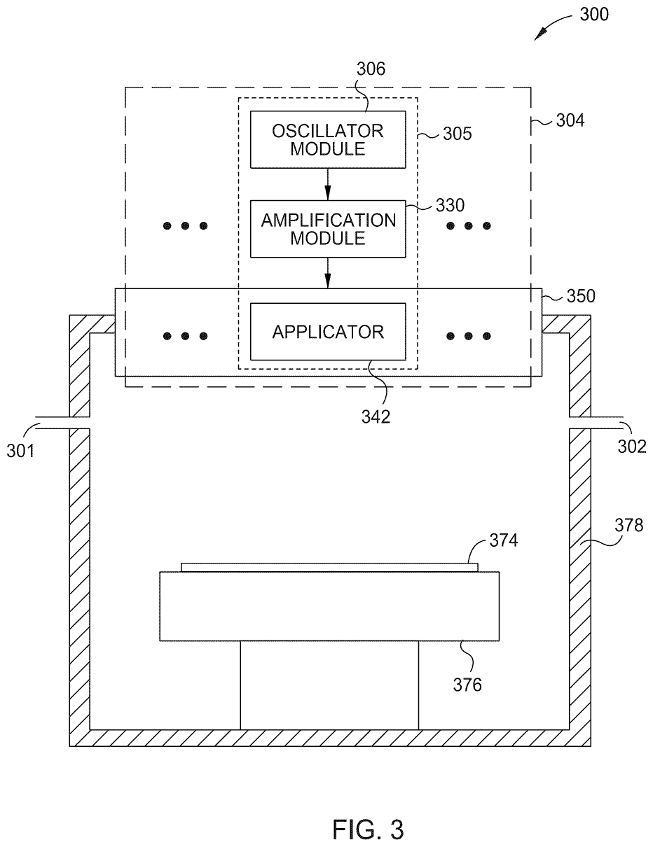

Referring now to FIG. 3-6, a series of illustrations depicting a microwave processing tool 300 is shown, in accordance with an embodiment. The microwave processing tool 300 generates microwaves that are useful for low temperature reduction of metal oxides.

Referring now to FIG. 3, a cross-sectional illustration of a microwave processing tool 300 (referred to as processing tool 300 for short) is shown, according to an embodiment. The processing tool may emit high-frequency electromagnetic radiation. In some embodiments, one or more of the pre-clean chambers 110 and 114, or even chambers 132-140, may include the processing tool 300. As used herein, “high-frequency” electromagnetic radiation includes radio frequency radiation, very-high-frequency radiation, ultra-high-frequency radiation, and microwave radiation. “High-frequency” may refer to frequencies between 0.1 MHz and 300 GHz.

Generally, embodiments include a processing tool 300 that includes a chamber 378. In processing tool 300, the chamber 378 may be a vacuum chamber. A vacuum chamber may include a pump (not shown) for removing gases from the chamber to provide the desired vacuum. Additional embodiments may include a chamber 378 that includes one or more gas lines 370 for providing processing gasses into the chamber 378 and exhaust lines 372 for removing byproducts from the chamber 378. While not shown, it is to be appreciated that gas may also be injected into the chamber 378 through a source array 350 (e.g., as a showerhead) for evenly distributing the processing gases over a substrate 374.

In an embodiment, the substrate 374 may be supported on a chuck 376. For example, the chuck 376 may be any suitable chuck, such as an electrostatic chuck. The chuck 376 may also include cooling lines and/or a heater to provide temperature control to the substrate 374 during processing. Due to the modular configuration of the high-frequency emission modules described herein, embodiments allow for the processing tool 300 to accommodate any sized substrate 374. For example, the substrate 374 may be a semiconductor wafer (e.g., 200 mm, 300 mm, 450 mm, or larger). Alternative embodiments also include substrates 374 other than semiconductor wafers. For example, embodiments may include a processing tool 300 configured for processing glass substrates, (e.g., for display technologies).

According to an embodiment, the processing tool 300 includes a modular high-frequency emission source 304. The modular high-frequency emission source 304 may comprise an array of high-frequency emission modules 305. In an embodiment, each high-frequency emission module 305 may include an oscillator module 306, an amplification module 330, and an applicator 342. As shown, the applicators 342 are schematically shown as being integrated into the source array 350.

In an embodiment, the oscillator module 306 and the amplification module 330 may comprise electrical components that are solid state electrical components. In an embodiment, each of the plurality of oscillator modules 306 may be communicatively coupled to different amplification modules 330. For example, each oscillator module 306 may be electrically coupled to a single amplification module 330. In an embodiment, the plurality of oscillator modules 306 may generate incoherent electromagnetic radiation. Accordingly, the electromagnetic radiation induced in the chamber 378 will not interact in a manner that results in an undesirable interference pattern.

In an embodiment, each oscillator module 306 generates high-frequency electromagnetic radiation that is transmitted to the amplification module 330. After processing by the amplification module 330, the electromagnetic radiation is transmitted to the applicator 342. In an embodiment, the applicators 342 each emit electromagnetic radiation into the chamber 378. In some embodiments, the applicators 342 couple the electromagnetic radiation to the substrate 374 in the chamber 378. In some embodiments, the applicators 342 couple the electromagnetic radiation to the processing gasses in the chamber 378 to provide energy thereto, without forming a plasma.

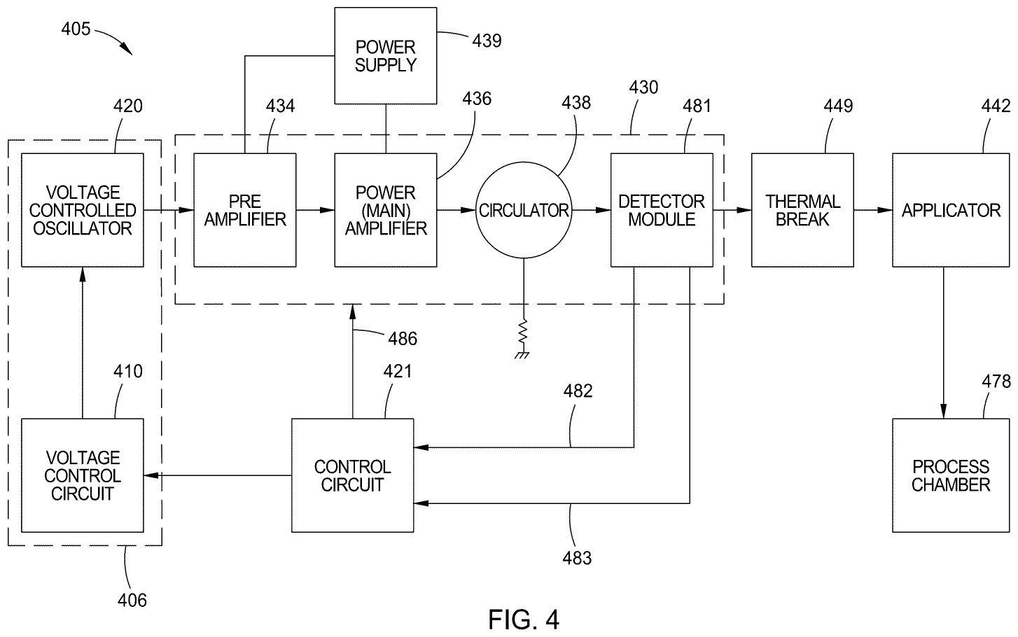

Referring now to FIG. 4, a schematic of a solid state high-frequency emission module 405 is shown, in accordance with an embodiment. In an embodiment, the high-frequency emission module 405 comprises an oscillator module 406. The oscillator module 406 may include a voltage control circuit 410 for providing an input voltage to a voltage controlled oscillator 420 in order to produce high-frequency electromagnetic radiation at a desired frequency. The voltage controlled oscillator 420 is an electronic oscillator whose oscillation frequency is controlled by the input voltage. According to an embodiment, the input voltage from the voltage control circuit 410 results in the voltage controlled oscillator 420 oscillating at a desired frequency.

According to an embodiment, the electromagnetic radiation is transmitted from the voltage controlled oscillator 420 to an amplification module 430. The amplification module 430 may include a driver/pre-amplifier 434, and a main power amplifier 436 that are each coupled to a power supply 439. According to an embodiment, the amplification module 430 may operate in a pulse mode. For example, the amplification module 430 may have a duty cycle between 1% and 99%. In a more particular embodiment, the amplification module 430 may have a duty cycle between approximately 15% and 50%.

In an embodiment, the electromagnetic radiation may be transmitted to the thermal break 449 and the applicator 442 after being processed by the amplification module 430. However, part of the power transmitted to the thermal break 449 may be reflected back due to the mismatch in the output impedance. Accordingly, some embodiments include a detector module 481 that allows for the level of forward power 483 and reflected power 482 to be sensed and fed back to the control circuit module 421. It is to be appreciated that the detector module 481 may be located at one or more different locations in the system (e.g., between the circulator 438 and the thermal break 449). In an embodiment, the control circuit module 421 interprets the forward power 483 and the reflected power 482, and determines the level for the control signal 485 that is communicatively coupled to the oscillator module 406 and the level for the control signal 486 that is communicatively coupled to the amplification module 430. In an embodiment, control signal 485 adjusts the oscillator module 406 to optimize the high-frequency radiation coupled to the amplification module 430. In an embodiment, control signal 486 adjusts the amplification module 430 to optimize the output power coupled to the applicator 442 through the thermal break 449. In an embodiment, the feedback control of the oscillator module 406 and the amplification module 430, in addition to the tailoring of the impedance matching in the thermal break 449, may allow for the level of the reflected power to be less than approximately 5% of the forward power. In some embodiments, the feedback control of the oscillator module 406 and the amplification module 430 may allow for the level of the reflected power to be less than approximately 2% of the forward power.

Accordingly, embodiments allow for an increased percentage of the forward power to be coupled into the processing chamber 478, and increases the available power provided to the process gases disposed within the processing volume. Furthermore, impedance tuning using a feedback control is superior to impedance tuning in typical slot-plate antennas. In slot-plate antennas, the impedance tuning involves moving two dielectric slugs formed in the applicator. This involves mechanical motion of two separate components in the applicator, which increases the complexity of the applicator.

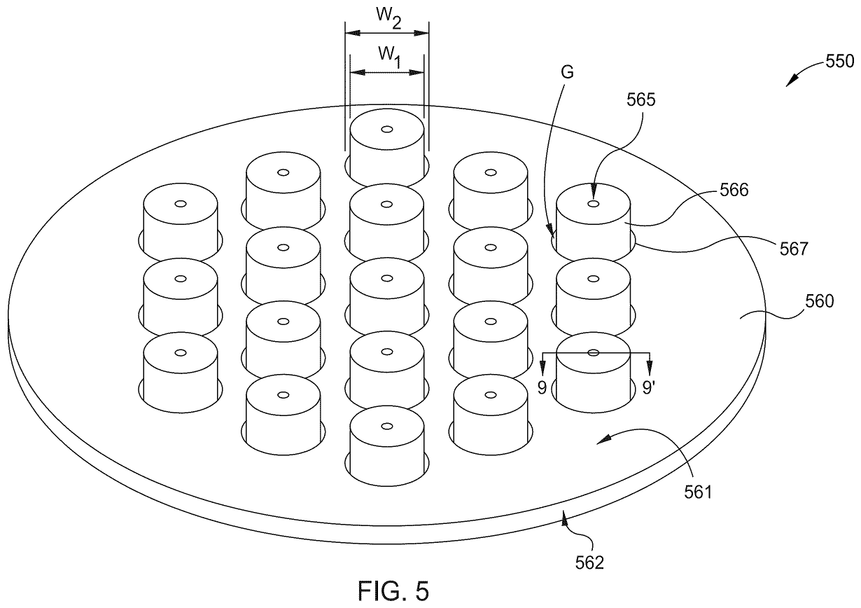

Referring now to FIG. 5, a perspective view illustration of a source array 550 is shown, in accordance with an embodiment. In an embodiment, the source array 550 comprises a dielectric plate 560. A plurality of cavities 567 are disposed into a first surface 561 of the dielectric plate 560. The cavities 567 do not pass through to a second surface 562 of the dielectric plate 560. The source array 550 may further include a plurality of dielectric resonators 566. Each of the dielectric resonators 566 may be in a different one of the cavities 567. Each of the dielectric resonators 566 may comprise a hole 565 in the axial center of the dielectric resonator 566.

In an embodiment, the dielectric resonators 566 may have a first width W1, and the cavities 567 may have a second width W2. The first width W1 of the dielectric resonator 566 is smaller than the second width W2 of the cavities 567. The difference in the widths provides a gap G between a sidewall of the dielectric resonators 566 and a sidewall of the cavity 567. In the illustrated embodiment, each of the dielectric resonators 566 are shown as having a uniform width W1. However, it is to be appreciated that not all dielectric resonators 566 of a source array 550 need to have the same dimensions.

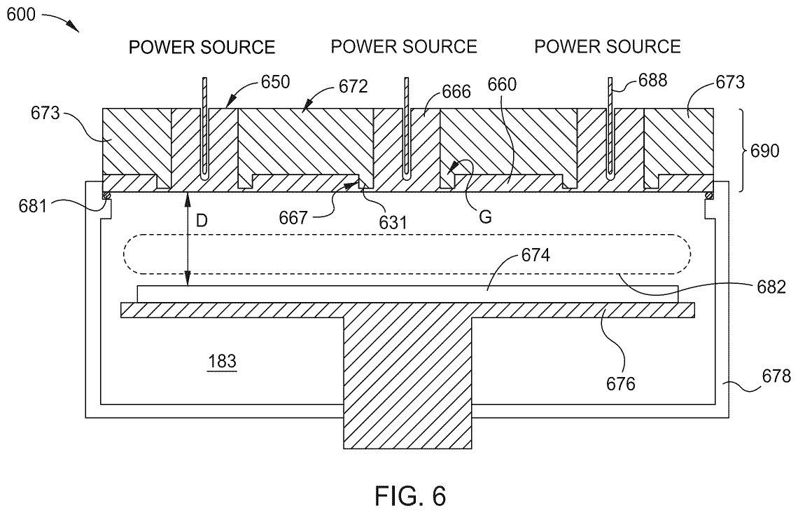

Referring now to FIG. 6, a cross-sectional illustration of a processing tool 600 that includes an assembly 690 is shown, in accordance with an embodiment. In an embodiment, the processing tool comprises a chamber 678 that is sealed by an assembly 690. For example, the assembly 690 may rest against one or more O-rings 681 to provide a vacuum seal to an interior volume 683 of the chamber 678. In other embodiments, the assembly 690 may interface with the chamber 678. That is, the assembly 690 may be part of a lid that seals the chamber 678. In an embodiment, the processing tool 600 may comprise a plurality of processing volumes (which may be fluidically coupled together), with each processing volume having a different assembly 690. In an embodiment, a chuck 676 or the like may support a substrate 674 (e.g., wafer, workpiece, etc.). The substrate 674 may be a distance D from the assembly 690. That is, the chamber 678 may be a vacuum chamber. In an embodiment, the assembly 690 comprises a source array 650 and a housing 672. The source array 650 may comprise a dielectric plate 660 and a plurality of dielectric resonators 666 extending up from the dielectric plate 660. Cavities 667 into the dielectric plate 660 may surround each of the dielectric resonators 666. Sidewalls of the cavity 667 are separated from the sidewall of the dielectric resonator 666 by a gap G. The dielectric plate 660 and the dielectric resonators 666 of the source array 650 may be a monolithic structure, or the dielectric plate 660 and the dielectric resonators 666 may be discrete components.

The housing 672 include rings 631 that fit into the gaps G. In an embodiment, the rings 631 and the conductive body 673 of the housing 672 are a monolithic structure, or the conductive body 673 and the rings 631 may be discrete components. The housing 672 may having openings sized to receive the dielectric resonators 666. In an embodiment, monopole antennas 688 may extend into holes in the dielectric resonators 666. The monopole antennas 688 are each electrically coupled to power sources (e.g., high-frequency emission modules 305).

Embodiments of this disclosure utilize a microwave process. Without being bound by theory the microwave process described herein is believed to weaken the bonds of metal oxide materials with the help of vibration-rotation motion of metal oxide dipoles at microwave frequencies. The disclosed methods utilize E-field for dipole rotation and B-field for eddy current, which leads to heating of the metal oxide material with limited effects on other substrate materials. The energy of the microwaves can be tuned low enough that it doesn't substantially damage dielectric materials (e.g., no plasma, low temperature). Further, the disclosed methods are self-limiting by only affecting metal oxides and not metal materials.

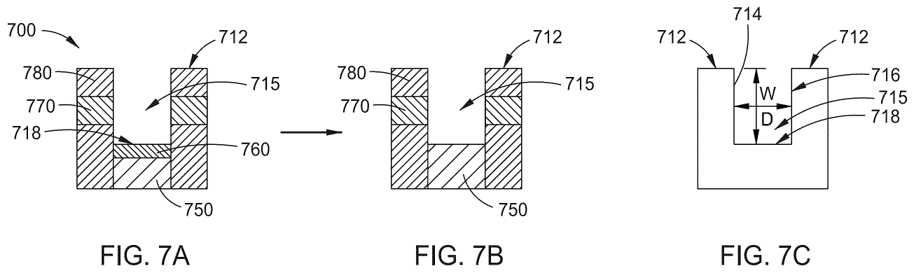

Referring to FIG. 7A and FIG. 7B, a method 700 begins with a metal oxide layer 760 on a metal material 750. At operation 710, the metal oxide layer 760 is exposed to microwave radiation. As used in this regard, exposing a substrate to a “microwave radiation” should be understood to comprise activating a microwave source and exposing the metal oxide layer 760 to the generated microwave radiation. In some embodiments, the microwave process does not generate a reactive plasma. Stated differently, in some embodiments, the metal oxide layer is not exposed to a plasma.

The metal material 750 may comprise any suitable metal. In some embodiments, the metal material 750 and the metal oxide layer 760 comprise the same metal or metals. In some embodiments, the metal material comprises or consists essentially of one or more of molybdenum, tungsten, ruthenium, copper, cobalt, tantalum or titanium.

In some embodiments, the metal oxide layer 760 has a thickness in a range of about 20 Å to about 30 Å. In some embodiments, the method 700 reduces a thickness of the metal oxide layer 760 in a range of about 10 Å to about 30 Å, or in a range of about 20 Å to about 30 Å, or in a range of about 15 Å to about 25 Å. In some embodiments, the method 700 reduces the entire metal oxide layer to pure metal.

In some embodiments, the microwave process at operation 710 comprises exposing the metal oxide layer 760 to a gas flow. In some embodiments, the gas flow is continuous and the microwave exposure is continuous. Stated differently, in some embodiments, neither the gas flow nor the microwave sources are pulsed during the microwave process.

In some embodiments, the gas flow comprises an inert gas. Without being bound by theory, it is believed that exposure to the inert gas flow may help facilitate removal of volatile reaction byproducts. In some embodiments, the inert gas comprises or consists essentially of helium (He) or argon (Ar). In some embodiments, the inert gas comprises or consists essentially of a hydrocarbon (e.g., CH₄, C₂H₆, C₂H₄, C₂H₂). In some embodiments, the inert gas comprises or consists essentially of CO₂.

In some embodiments, the gas flow comprises a reactant. Without being bound by theory, it is believed that exposure to the reactant gas flow may react with activated oxygen atoms from the metal oxide layer 760 to form volatile species that are more easily purged from the processing chamber. In some embodiments, the reactant comprises or consists essentially of one or more of hydrogen gas (H₂) or carbon monoxide (CO).

In some embodiments, the method 700 is performed at relatively low temperatures. The relative low temperatures advantageously result in decreased damage to surrounding materials (e.g., dielectrics). In some embodiments, the metal material is maintained at temperature in a range of about 300° C. to about 400° C. In some embodiments, the metal material is maintained at a temperature of less than or equal to about 300° C. In some embodiments, the metal material is maintained at temperature in a range of about 20° C. to about 50° C. or in a range of about 20° C. to about 100° C.

In some embodiments, the period of exposure is controlled to reduce a predetermined depth of the metal oxide layer 760. In some embodiments, the period is in a range of about 60 seconds to about 600 seconds, in a range of about 60 seconds to about 300 seconds, or in a range of about 30 seconds to about 120 seconds.

In some embodiments, the power of microwave array is in a range of about 800 W to about 8000 W, or in a range of about 900 W to about 5000 W, or in a range of about 1000 W to about 3000 W.

In some embodiments, the pressure of the chamber may be controlled. In some embodiments, the pressure is maintained in a range of about 1 mTorr to about 10 Torr, or in a range of about 10 mTorr to about 1 Torr, or in a range of about 10 mTorr to about 100 mTorr, or in a range of about 50 m Torr to about 75 m Torr.

As shown in FIG. 7C, in some embodiments, the metal material 750 is located at the bottom 718 of a substrate feature 715. The feature 715 has sidewalls 714, 716. In some embodiments, at least a portion of the sidewalls 714, 716 comprise a low-k material (e.g., low-k material 770 of either FIG. 7A or 7B). In some embodiments, the top surface 712 of the feature comprises a high-k dielectric (e.g., high-k dielectric 780 of either FIG. 7A or 7B). In some embodiments, the high-k dielectric (e.g., high-k dielectric 780 of either FIG. 7A or 7B) comprises silicon nitride.

In some embodiments, the low-k material comprises SiOC. In some embodiments, the low-k material of the sidewalls 714, 716 is substantially undamaged by the method 700. As used in this regard, the dielectric is “substantially undamaged” if the normalized loss of carbon/silicon is less than or equal to about 30%.

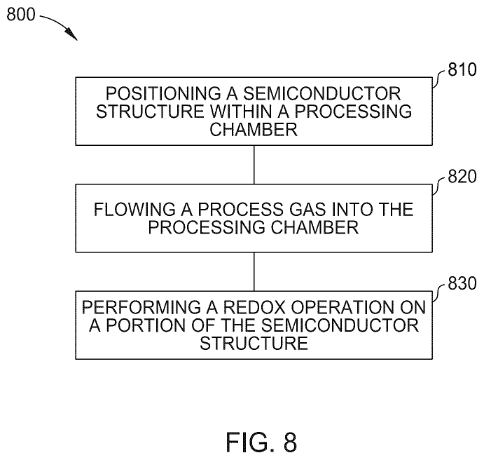

FIG. 8 depicts a process flow diagram of a method 800 of processing a substrate to, for example, form middle-of-line (MOL) and back-end-of-line (BEOL) structures, according to one or more embodiments of the present disclosure. The method 800 includes positioning a semiconductor structure within a processing chamber (operation 810), flowing a process gas into the process chamber (operation 820), and performing a redox operation on a portion of the semiconductor structure (operation 830).

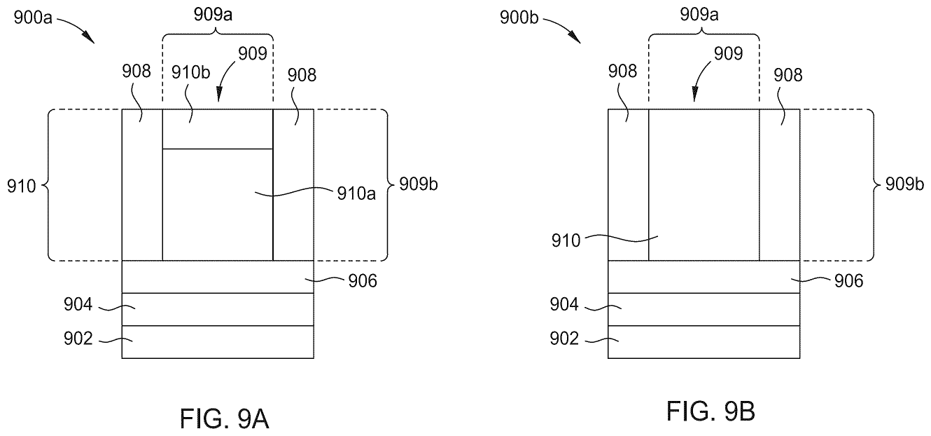

FIG. 9A-9B illustrate cross-sectional views of a semiconductor structure (e.g., 900a and 900b, respectively) in accordance with one or more embodiments described herein. Although FIG. 9A-9B are described in relation to the method 800, the structures disclosed in FIG. 9A-9B are not limited to the method 800, but instead may stand alone as structures independent of the method 800. Similarly, although the method 800 is described in relation to FIG. 9A-9B, the method 800 is not limited to the structures disclosed in FIG. 9A-9B but instead may stand alone independent of the structures disclosed in FIG. 9A-9B. It should be understood that FIG. 9A-9B illustrate only partial schematic views of the semiconductor device structure (e.g., 900a and 900b, respectively), and the semiconductor device structure (e.g., 900a and 900b, respectively) may contain any number of transistors or other devices and additional materials having aspects as illustrated in the figures. It should also be noted that although the method 800 illustrated in FIG. 8 is described sequentially, other process sequences that include one or more operations that have been omitted and/or added, and/or has been rearranged in another desirable order, fall within the scope of the embodiments of the disclosure provided herein.

The term “substrate” as used herein refers to a layer of material that serves as a basis for subsequent processing operations. The substrate may be a silicon based material or any suitable insulating materials or conductive materials as needed. The substrate may include a material such as crystalline silicon (e.g., Si<100> or Si<111>), silicon oxide, strained silicon, silicon germanium, doped or undoped polysilicon, doped or undoped silicon wafers and patterned or non-patterned wafers, silicon on insulator (SOI), carbon doped silicon oxides, silicon nitride, doped silicon, germanium, gallium arsenide, glass, or sapphire.

FIG. 9A depicts a semiconductor structure 900a prior to undergoing the method 800. The semiconductor structure 900a may include a SiO₂ layer 904 deposited on a substrate surface 902. The semiconductor structure 900a may also include a hardmask layer 906 deposited over the SiO₂ layer 904. The semiconductor structure 900a may also include one or more layers 908 deposited over the surface of the hardmask layer 906. The one or more layers 908 may independently include a low-k dielectric material. The low-k dielectric material may include a silicon carbide oxide material or a carbon doped silicon oxide material, for example BLACK DIAMOND® II low-k dielectric material, available from Applied Materials, Inc., located in Santa Clara, California.

In some embodiments, the one or more layers 908 may be organized and/or deposited in such a way to provide a gap 909 to the surface of the semiconductor structure 900a, thus producing a textured/patterned surface to the semiconductor structure 900a. The one or more layers 908 of the semiconductor structure 900a may be organized such that the gap 909 has a gap width 909a (e.g., distance/space between the interior surfaces of a feature formed in the one or more layers 908) of about 10 nm to about 50 nm, such as about 20 nm to about 40 nm, such as about 25 nm to about 35 nm, alternatively about 10 nm to about 20 nm, alternatively about 20 nm to about 25 nm, alternatively about 25 nm to about 30 nm, alternatively about 30 nm to about 35 nm, alternatively about 35 nm to about 40 nm, alternatively about 40 nm to about 50 nm. In at least one embodiment, the gap 909 has a gap height 909b (e.g., distance between the surface of the hardmask layer 906 and the top surface of the one or more layers 908) of about 20 nm to about 100 nm, such as about 40 nm to about 80 nm, such as about 50 nm to about 70 nm, alternatively about 20 nm to about 40 nm, alternatively about 40 nm to about 50 nm, alternatively about 50 nm to about 60 nm, alternatively about 60 nm to about 70 nm, alternatively about 70 nm to about 80 nm, alternatively about 80 nm to about 100 nm.

In some embodiments, the semiconductor structure 900a includes a metal material 910 deposited in the gap 909 formed by the one or more layers 908. The metal material 910 may include one or more metal layers, such as one or more molybdenum (Mo) based layers, deposited in the gap 909 formed by the one or more layers 908. For example, the metal material 910 of the semiconductor structure 900a can include, but is not limited to, a first layer 910a deposited over a contact metal layer (not shown) or an interconnect metal layer (not shown) and in some cases a portion of the hardmask layer 906, and a second layer 910b disposed over the first layer 910a. In some embodiments, the first layer 910a and the second layer 910b are composed of different metal compositions and/or are deposited via different deposition methods. For instance, in at least one embodiment, the first layer 910a is composed of Mo and the second layer 910b is composed of MoOx. The first layer 910a and the second layer 910b may be deposited either sequentially or simultaneously. Additionally, the first layer 910a and the second layer 910b independently may be deposited by a method selected from physical vapor deposition (PVD) and chemical vapor deposition (CVD). In some embodiments, the gap 909 is substantially filled with metal material 910 such that the gap width 909a and the gap height 909b is substantially encompassed with the metal material 910. The height and width of the metal material 910, and/or the one or more metal layers thereof, may be substantially the same as the gap width 909a and the gap height 909b.

In some embodiments, the semiconductor structure 900a includes a MoOx layer (e.g., second layer 910b) resulting from one or more semiconductor fabrication/processing procedures. It may be desired to remove the MoOx layer (e.g., second layer 910b) from the semiconductor structure 900a without reducing the height or width of the metal material 910 within the gap 909. Furthermore, removal of such MoOx layers should not come at the expense of damaging the low-k dielectric materials of the one or more layers 908. As such, the method 800 for processing a semiconductor structure (e.g., semiconductor structure 900a) utilizes a redox operation to convert the MoOx layer (e.g., second layer 910b) to a Mo containing layer via a reduction reaction.

Referring back to the method 800, operation 810 includes positioning a semiconductor structure 900a into a processing chamber. At operation 820, a process gas is flowed into the processing chamber. The process gas may include carbon monoxide (CO). In at least one embodiment, the process gas includes H₂. The process gas may be flowed into the processing chamber at a gas flow rate of about 0.01 sccm to about 45,000 sccm, such as about 100 sccm to about 45,000 sccm, such as about 1,000 sccm to about 45,000 sccm, such as about 2,000 sccm to about 45,000 sccm, such as about 3,000 sccm to about 45,000 sccm, such as about 10,000 sccm to about 45,000 sccm, alternatively about 0.01 sccm to about 100 sccm, alternatively about 100 sccm to about 1,000 sccm, alternatively about 1,000 sccm to about 2,000 sccm, alternatively about 2,000 sccm to about 3,000 sccm, alternatively about 3,000 sccm to about 10,000 sccm, alternatively about 10 sccm to about 2,000 sccm. In at least one embodiment, the process gas is flown into the processing chamber continuously throughout the duration of the method 800.

At operation 830 of the method 800, a redox operation is performed on the semiconductor structure 900a to convert the MoOx layer to a Mo layer. During the redox operation of operation 830, the temperature within the processing chamber may be from about 100° C. to about 500° C., such as about 150° C. to about 450° C., such as about 200° C. to about 400° C., such as about 250° C. to about 350° C., alternatively about 100° C. to about 150° C., alternatively about 150° C. to about 200° C., alternatively about 200° C. to about 250° C., alternatively about 250° C. to about 300° C., alternatively about 300° C. to about 350° C., alternatively about 350° C. to about 400° C., alternatively about 400° C. to about 450° C., alternatively about 450° C. to about 500° C. The pressure within the processing chamber during the redox operation may be from about 10 mTorr to about 760 Torr, such as about 10 Torr to about 760 Torr, such as about 250 Torr to about 760 Torr, such as about 250 Torr to about 530 Torr, alternatively about 10 Torr to about 100 Torr, alternatively about 100 Torr to about 250 Torr, alternatively about 250 Torr to about 400 Torr, alternatively about 400 Torr to about 550 Torr, alternatively about 500 Torr to about 760 Torr, alternatively about 100 Torr to about 760 Torr. The redox operation of operation 830 may be performed for about 1 second(s) to about 360 s, such as about 60 s to about 300 s, such as about 120 s to about 240 s, alternatively about 1 s to about 60 s, alternatively about 60 s to about 120 s, alternatively about 120 s to about 180 s, alternatively about 180 s to about 240 s, alternatively about 240 s to about 300 s, alternatively about 300 s to about 360 s.

In some embodiments, a microwave energy is applied to the process gas during the redox operation of operation 830. In at least one embodiment, applying the microwave energy to the process gas induces a plasma within the processing chamber. In at least one embodiment, the microwave energy applied during processing is provided at a power level at which the delivered microwave energy does not generate a plasma. Without being bound by theory, the delivery of microwave energy that is at a non-plasma generating power level can significantly reduce the amount of damage to the materials (e.g., dielectric and metal materials) in the semiconductor structure due to plasma generated ion bombardment of the materials within the semiconductor structure. By using a non-plasma generating mode, the low-k damage can be 10% to 50% lower than the plasma mode, as the energetic species (e.g., hydrogen radicals and ions) are not introduced during the process. In one example, a non-plasma generating power level will include a microwave energy power level that is between about 1% to about 10% below a lowest power level that generates a plasma during a process that includes a desired gas composition and pressure level. The microwave energy applied to the process gas during the redox operation may be applied at a power of about 0.1 W to about 180 W, such as about 1 W to about 180 W, such as about 10 W to about 180 W, such as about 100 W to about 180 W. In at least one embodiment, the microwave energy is applied to the process gas at a frequency between about 2.0 GHz and 2.5 GHZ. In at least one embodiment, the microwave energy is applied to the process gas continuously throughout the redox operation 830. In at least one embodiment, the redox operation includes applying the microwave energy to the process gas for about 1 s to about 360 s, such as about 60 s to about 300 s, such as about 120 s to about 240 s, alternatively about 1 s to about 60 s, alternatively about 60 s to about 120 s, alternatively about 120 s to about 180 s, alternatively about 180 s to about 240 s, alternatively about 240 s to about 300 s, alternatively about 300 s to about 360 s.

In at least one embodiment, the processing chamber is purged after operation 830 to remove contaminants therefrom. In at least one embodiment, operation 830 may be repeated such that the semiconductor structure 900a undergoes multiple redox operation cycles. In such instances, operation 830 may be performed for 1 cycle to about 30 cycles, such as for 1 cycle to 15 cycles, such as for 1 cycle to 10 cycles, such as for 1 cycle to 5 cycles.

Unlike conventional plasma treatment processes (e.g., remote plasma and/or inductively coupled plasma sources), the redox operation of operation 830 may be conducted at higher pressures relative to such processes. Such high pressures require higher process gas flows to maintain such pressure. The processing conditions of the redox operation can provide an alternative treatment route for removing/treating semiconductor structures having a MoOx content. Notably, the processing conditions of the redox operation can treat semiconductor structures having a MoOx content at a higher treatment efficiency while also limiting the damage applied to the low-k dielectric material, as compared to conventional plasma treatment processes. Furthermore, the redox operation of operation 830 may include applying a microwave energy to the process gas introduced to the processing chamber. The microwave energy may be applied to the process gas at a non-plasma generating power level so as to not induce the formation of a plasma over a surface of a substrate. In doing so, the processing conditions described herein can provide comparable and/or enhanced MoOx content reduction and limited damage to the surrounding low-k dielectric material as convention plasma treatment processes without the need to form a potentially damaging plasma.

FIG. 9B illustrates a semiconductor structure 900b that has been subjected to the method 800. As shown, the MoOx layer (e.g., second layer 910b) of the metal material 910 deposited in the gap 909 of the semiconductor structure 900a is absent in the semiconductor structure 900b. The absence of the MoOx layer in the semiconductor structure 900b is due to the redox operation reducing the MoOx to Mo (metallic) to form a Mo layer having no distinguishable interface between the first layer 910a and the second layer 910b of the metal material 910.

In at least one embodiment, greater than about 80% of the MoOx within the metal material 910 is reduced to Mo after subjecting a semiconductor structure to the method 800, such as greater than about 85%, such as greater than about 90%, such as greater than about 95%, such as greater than about 99.9%. In some embodiments, about 80% to about 99.9% of the MoOx within the metal material 910 is reduced to Mo after subjecting a semiconductor structure to the method 800, such as about 85% to about 95%, such as about 87.5% to about 92.5%, alternatively about 80% to about 85%, such as about 85% to about 87.5%, such as about 87.5% to about 90%, such as about 90% to about 92.5%, such as about 92.5% to about 95%, such as about 95% to about 99.9%. In at least one embodiment, the final MoOx content within the metal material 910 (e.g., after undergoing the method 800) is about 80% to about 99.9% less than the initial MoOx content, such as about 85% to about 95% less, such as about 87.5% to about 92.5% less, alternatively about 80% to about 85% less, such as about 85% to about 87.5% less, such as about 87.5% to about 90% less, such as about 90% to about 92.5% less, such as about 92.5% to about 95% less, such as about 95% to about 99.9% less.

In some embodiments, the metal layer 910 has a thickness (as determined in relation to the gap height 909b) of about 100 Å to about 500 Å prior to undergoing the method 800, such as about 150 Å to about 450 Å, such as about 200 Å to about 400 Å, such as about 250 Å to about 350 Å, alternatively about 100 Å to about 150 Å, alternatively about 150 Å to about 200 Å, alternatively about 200 Å to about 250 Å, alternatively about 250 Å to about 300 Å, alternatively about 300 Å to about 350 Å, alternatively about 350 Å to about 400 Å, alternatively about 400 Å to about 450 Å, alternatively about 450 Å to about 500 Å. After being subjected to the method 800, the metal layer 910 has a thickness of about 100 Å to about 500 Å, such as about 150 Å to about 450 Å, such as about 200 Å to about 400 Å, such as about 250 Å to about 350 Å, alternatively about 100 Å to about 150 Å, alternatively about 150 Å to about 200 Å, alternatively about 200 Å to about 250 Å, alternatively about 250 Å to about 300 Å, alternatively about 300 Å to about 350 Å, alternatively about 350 Å to about 400 Å, alternatively about 400 Å to about 450 Å, alternatively about 450 Å to about 500 Å. In at least one embodiment, the metal material 910 retains greater than about 60% of its initial thickness after undergoing the method 800, such as greater than about 70%, such as greater than about 80%, such as greater than about 90%, such as greater than about 95%, such as greater than about 99.9%. In at least one embodiment, the metal material 910 retains about 60% to about 90% of its initial thickness after undergoing the method 800, such as about 65% to about 85%, such as about 70% to about 80%, alternatively about 60% to about 65%, alternatively about 65% to about 70%, alternatively about 70% to about 75%, alternatively about 75% to about 80%, alternatively about 80% to about 85%, alternatively about 85% to about 90%. In at least one embodiment, the final thickness of the metal material 910 (e.g., after undergoing the method 800) is about 60% to about 90% less than the initial thickness, such as about 65% to about 85% less, such as about 70% to about 80% less, alternatively about 60% to about 65% less, alternatively about 65% to about 70% less, alternatively about 70% to about 75% less, alternatively about 75% to about 80% less, alternatively about 80% to about 85% less, alternatively about 85% to about 90% less.

As previously discussed, the removal of such MoOx layers should not come at the expense of damaging the low-k dielectric materials of the one or more layers 908. That is to say that the one or more layers 908 formed from the low-k dielectric materials should experience a minimized and/or eliminated loss in carbon content as a result of undergoing the method 800. In some embodiments, the method 800 results in a carbon loss of less than 1%, such as less than about 0.5%, such as less than about 0.1%, such as less than about 0.01%, such as less than about 0.001%. In at least one embodiment, the method 800 results in a carbon loss of about 0.001% to about 1%, such as about 0.01 to about 1%, such as about 0.1% to about 1%, such as about 0.5% to about 1%, alternatively about 0.001% to about 0.01%, alternatively about 0.01% to about 0.1%, alternatively about 0.1% to about 0.5%. In at least one embodiment, the final carbon content of the one or more layers 908 (e.g., after undergoing the method 800) is about 0.001% to about 1% less than the initial carbon content, such as about 0.01% to about 1% less, such as about 0.1% to about 1% less, such as about 0.5% to about 1% less, alternatively about 0.001% to about 0.01% less, alternatively about 0.01% to about 0.1% less, alternatively about 0.1% to about 0.5% less.

Reference throughout this specification to “one embodiment,” “certain embodiments,” “one or more embodiments” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in one embodiment” or “in an embodiment” in various places throughout this specification are not necessarily referring to the same embodiment of the disclosure. Furthermore, the particular features, structures, materials, or characteristics may be combined in any suitable manner in one or more embodiments.

Although the disclosure herein has been described with reference to particular embodiments, those skilled in the art will understand that the embodiments described are merely illustrative of the principles and applications of the present disclosure. It will be apparent to those skilled in the art that various modifications and variations can be made to the method and apparatus of the present disclosure without departing from the spirit and scope of the disclosure. Thus, the present disclosure can include modifications and variations that are within the scope of the appended claims and their equivalents.

What is claimed is:

1. A method, comprising:
positioning a semiconductor structure within a processing chamber, the semiconductor structure comprising:
an SiO₂ layer deposited on a substrate surface,
a hardmask layer deposited over the SiO₂ layer,
a feature formed from a low-k dielectric material deposited over a portion of the hardmask layer, and
a metal layer deposited in the feature, the metal layer comprising a molybdenum (Mo) layer and a molybdenum oxide layer (MoOx);
flowing a process gas into the processing chamber, the process gas comprising carbon monoxide; and
applying a microwave energy to the process gas to perform a redox operation on a portion of the semiconductor structure.

2. The method of claim 1, wherein the process gas is flowed into the processing chamber at a gas flow rate of about 0.01 sccm to about 45,000 sccm.

3. The method of claim 1, wherein the processing chamber is maintained at a temperature of about 100° C. to about 500° C. during the redox operation.

4. The method of claim 1, wherein the processing chamber is maintained at a pressure of about 10 mTorr to about 760 Torr during the redox operation.

5. The method of claim 1, wherein the redox operation is performed for about 1 second(s) to about 360 s.

6. The method of claim 1, wherein the microwave energy is applied to the process gas using a power of about 1 W to about 180 W.

7. The method of claim 1, wherein the microwave energy is applied to the process gas at a frequency of about 2 GHz to about 2.5 GHZ.

8. The method of claim 1, wherein the microwave energy is continuously applied to the process gas throughout the redox operation.

9. A method, comprising:
positioning a semiconductor structure within a processing chamber, the semiconductor structure comprising:
an SiO₂ layer deposited on a substrate surface,
a hardmask layer deposited over the SiO₂ layer,
a feature formed from a low-k dielectric material deposited over a portion of the hardmask layer, and
a metal layer deposited in the feature, the metal layer comprising a molybdenum (Mo) layer and a molybdenum oxide layer (MoOx);
flowing a process gas into the processing chamber, the process gas comprising carbon monoxide; and
applying a microwave energy to the process gas to perform a redox operation on a portion of the semiconductor structure, the microwave energy being applied at a first power level that is about 1% to about 10% below a second power level, wherein the second power level is a lowest power level that generates a plasma.

10. The method of claim 9, wherein the process gas is flowed into the processing chamber at a gas flow rate of about 0.01 sccm to about 45,000 sccm.

11. The method of claim 9, wherein the processing chamber is maintained at a temperature of about 100° C. to about 500° C. during the redox operation.

12. The method of claim 9, wherein the processing chamber is maintained at a pressure of about 10 mTorr to about 760 Torr during the redox operation.

13. The method of claim 9, wherein the redox operation is performed for about 1 second(s) to about 360 s.

14. The method of claim 9, wherein the microwave energy is applied to the process gas using a power of about 1 W to about 180 W.

15. The method of claim 9, wherein the microwave energy is applied to the process gas at a frequency of about 2 GHz to about 2.5 GHZ.

16. The method of claim 9, wherein the microwave energy is continuously applied to the process gas throughout the redox operation.

17. A method, comprising:
positioning a semiconductor structure within a processing chamber, the semiconductor structure comprising:
an SiO₂ layer deposited on a substrate surface,
a hardmask layer deposited over the SiO₂ layer,
a feature formed from a low-k dielectric material deposited over a portion of the hardmask layer, and
a metal layer deposited in the feature, the metal layer comprising a first layer comprising molybdenum (Mo) and a second layer comprising molybdenum oxide (MoOx);
flowing a process gas into the processing chamber, the process gas comprising carbon monoxide; and
applying a microwave energy to the process gas to perform a redox operation on a portion of the semiconductor structure, wherein greater than about 95% of the MoOx is converted to Mo.

18. The method of claim 17, wherein the microwave energy is applied to the process gas using a non-plasma generating power level.

19. The method of claim 17, further comprising:
purging the processing chamber subsequent the redox operation, and
applying a microwave energy to the process gas to perform a second redox operation.

20. The method of claim 17, wherein the microwave energy is applied to the process gas using a power of about 0.1 W to about 150 W at a frequency of about 2 GHz to about 2.5 GHZ.
